(19) United States
(12) Patent Application Publication
(10) Pub. No.: US 2026/0188595 A1
(43) Pub. Date: Jul. 2, 2026

(54) COMPOSITE ELECTRONIC COMPONENT AND BOARD HAVING COMPOSITE ELECTRONIC COMPONENT MOUNTED THEREON

(71) Applicant: SAMSUNG ELECTRO-MECHANICS CO., LTD., Suwon-si (KR)

(72) Inventors: Jeong Bong PARK, Suwon-si (KR); Han Bok LEE, Suwon-si (KR); Ki Ryeon PARK, Suwon-si (KR); Won Jun LEE, Suwon-si (KR)

(73) Assignee: SAMSUNG ELECTRO-MECHANICS CO., LTD., Suwon-si (KR)

(21) Appl. No.: 19/397,490

(22) Filed: Nov. 21, 2025

(30) Foreign Application Priority Data
Dec. 31, 2024 (KR) 10-2024-0202248

(51) Int. Cl. H01G 4/38; H01G 4/224; H05K 1/18

(52) U.S. Cl. CPC H01G 4/38; H01G 4/224; H05K 1/18; H05K 2201/10015

(57) ABSTRACT

A composite electronic component includes a plurality of multilayer electronic components respectively including a body including a capacitance formation portion including a dielectric layer, and an internal electrode, alternately disposed with the dielectric layer in a first direction, and a cover portion disposed on both side surfaces of the capacitance formation portion in the first direction, and an external electrode disposed on the body in a second direction, perpendicular to the first direction. An average dimension of the dielectric layer in the first direction is referred to as td, an average dimension of the first cover portion in the first direction is referred to as tc1, and an average dimension of the second cover portion in the first direction is referred to as tc2, 0.5×td≤tc1<tc2 is satisfied.

### CROSS-REFERENCE TO RELATED APPLICATION(S)

This application claims benefit of priority to Korean Patent Application No. 10-2024-0202248 filed on Dec. 31, 2024 in the Korean Intellectual Property Office, the disclosure of which is incorporated herein by reference in its entirety.

### TECHNICAL FIELD

The present disclosure relates to a composite electronic component and a board having the same mounted thereon.

A multilayer ceramic capacitor (MLCC), a multilayer electronic component, is a chip-type condenser mounted on the printed circuit boards of various types of electronic products such as imaging devices, including a liquid crystal display (LCD) and a plasma display panel (PDP), computers, smartphones, and mobile phones, and serves to charge or discharge electricity therein or therefrom.

The multilayer ceramic capacitor may be used as a component of various electronic devices due to having a small size, ensuring high capacitance and being easily mounted. With the miniaturization and high-output power of various electronic devices such as computers and mobile devices, demand for miniaturization and implementation of high capacitance of multilayer ceramic capacitors has also been increasing.

Such multilayer ceramic capacitors have recently been applied to power drive systems in automobiles. Multilayer ceramic capacitors for automobiles are required to exhibit excellent high-temperature reliability, moisture-resistant reliability, and impact resistance. In particular, cracks may occur in a ceramic body due to external impacts, acoustic noise, or bending stress, which may cause defects in a component. To address such an issue, a method of attaching a frame formed of a metal or the like to an external electrode has been used to mitigate external impacts, thereby improving impact resistance of the component.

However, in a configuration in which frames are attached to a plurality of multilayer ceramic capacitors, some elements of the multilayer ceramic capacitor may excessively protect a capacitance formation region, resulting in unnecessary mounting volume.

### SUMMARY

An aspect of the present disclosure is to provide a composite electronic component having a reduced mounting volume.

Another aspect of the present disclosure is to provide a composite electronic component having improved dielectric capacitance properties.

Another aspect of the present disclosure is to provide a composite electronic component having improved withstand voltage properties.

However, the aspects of the present disclosure are not limited to those set forth herein, and will be more easily understood in the course of describing specific example embodiments of the present disclosure.

According to an aspect of the present disclosure, there is provided a composite electronic component including a plurality of multilayer electronic components, each multilayer electronic component among the plurality of multilayer electronic components including: a body including: a capacitance formation portion including a dielectric layer, and internal electrodes alternately disposed with the dielectric layer in a first direction, and a cover portion that includes a first cover portion and a second cover portion, the first cover portion is disposed on a first side surface of the capacitance formation portion in the first direction, and the second cover portion is disposed on a second side surface of the capacitance formation portion in the first direction, and an external electrode disposed on the body in a second direction that is perpendicular to the first direction. The plurality of multilayer electronic components may include a pair of multilayer electronic components disposed to be in contact with each other in the first direction. When, among the pair of multilayer electronic components, first cover portions are disposed to be adjacent to each other in the first direction, and second cover portions are disposed to not be adjacent to each other in the first direction, and an average dimension of the dielectric layer in the first direction is referred to as td, an average dimension of the first cover portion in the first direction is referred to as tc1, and an average dimension of the second cover portion in the first direction is referred to as tc2, 0.5×td≤tc1<tc2 may be satisfied.

According to another aspect of the present disclosure, there is provided a composite electronic component including a plurality of multilayer electronic components, each multilayer electronic component among the plurality of multilayer electronic components including: a body including: a capacitance formation portion including: a dielectric layer, and internal electrodes alternately disposed with the dielectric layer in a first direction, and a cover portion that includes a first cover portion and a second cover portion, the first cover portion is disposed on a first side surface of the capacitance formation portion in the first direction, and the second cover portion is disposed on a second side surface of the capacitance formation portion in the first direction, and an external electrode disposed on the body in a second direction that is perpendicular to the first direction. The plurality of multilayer electronic components may be disposed to be in contact with each other in the first direction. When, among the plurality of multilayer electronic components, first cover portions are disposed to be adjacent to each other in the first direction, and second cover portions are disposed to not be adjacent to each other in the first direction, and an average dimension of the dielectric layer in the first direction is referred to as td, an average dimension of the first cover portion in the first direction is referred to as tc1, and an average dimension of the second cover portion in the first direction is referred to as tc2, 0.5×td≤tc1<tc2 may be satisfied.

According to another aspect of the present disclosure, there is provided a board having a composite electronic component mounted thereon, the board including a board, an electrode pad disposed on the board, and the composite electronic component. The composite electronic component may be mounted on the board so as to be bonded to the electrode pad.

According to example embodiments of the present disclosure, a composite electronic component may have a reduced mounting volume.

According to example embodiments of the present disclosure, a composite electronic component may have improved dielectric capacitance properties.

According to example embodiments of the present disclosure, a composite electronic component may have improved withstand voltage properties.

However, the various advantages and effects of the present disclosure are not limited to those set forth herein, and will be more easily understood in the course of describing specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic perspective view of a composite electronic component according to an example embodiment of the present disclosure;

FIG. 2 is a schematic cross-sectional view taken along line I-I′ of FIG. 1;

FIG. 3 is a schematic cross-sectional view taken along line II-II′ of FIG. 1;

FIG. 4 is a schematic perspective view of a composite electronic component according to another example embodiment of the present disclosure;

FIG. 5 is a schematic cross-sectional view taken along line III-III′ of FIG. 4; and

FIG. 6 is a schematic view of a board having the composite electronic component of FIG. 1 mounted thereon.

### DETAILED DESCRIPTION

Hereinafter, example embodiments of the present disclosure are described with reference to the accompanying drawings. The present disclosure may, however, be exemplified in many different forms and should not be construed as being limited to the specific example embodiments set forth herein. In addition, example embodiments of the present disclosure may be provided for a more complete description of the present disclosure to those skilled in the art. Accordingly, the shapes and sizes of the elements in the drawings may be exaggerated for clarity of description, and elements denoted by the same reference numerals in the drawings may be the same elements.

In order to clearly illustrate the present disclosure, portions not related to the description are omitted, and sizes and thicknesses are magnified in order to clearly represent layers and regions, and similar portions having the same functions within the same scope are denoted by similar reference numerals throughout the specification. Throughout the specification, when an element is referred to as “comprising” or “including,” it means that it may include other elements as well, rather than excluding other elements, unless specifically stated otherwise.

In the drawings, a Z-direction may be defined as a first direction, a stacking direction, or a thickness (T) direction, an X-direction may be defined as a second direction or a length (L) direction, and a Y-direction may be defined as a third direction or a width (W) direction.

### Multilayer Electronic Component

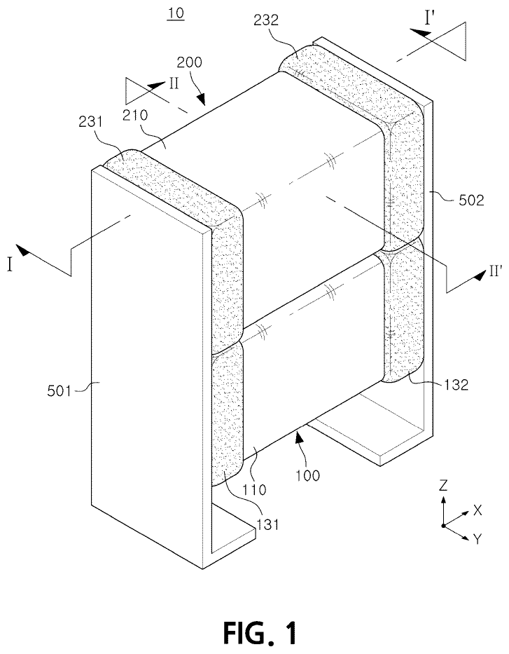

FIG. 1 is a schematic perspective view of a composite electronic component according to an example embodiment of the present disclosure.

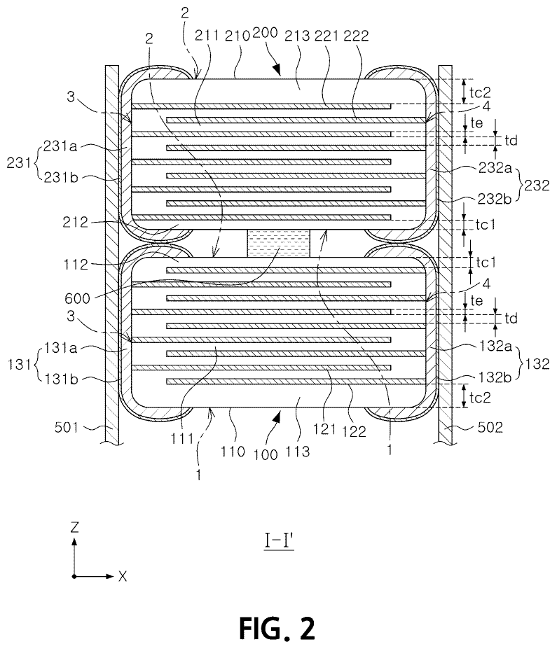

FIG. 2 is a schematic cross-sectional view taken along line I-I′ of FIG. 1.

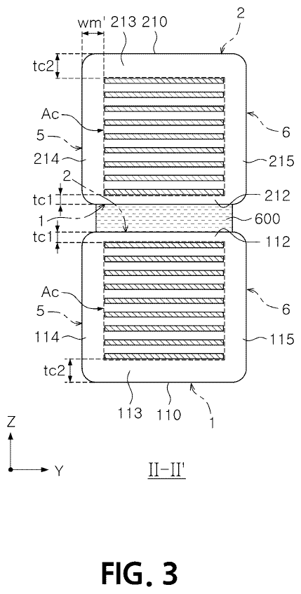

FIG. 3 is a schematic cross-sectional view taken along line II-II′ of FIG. 1.

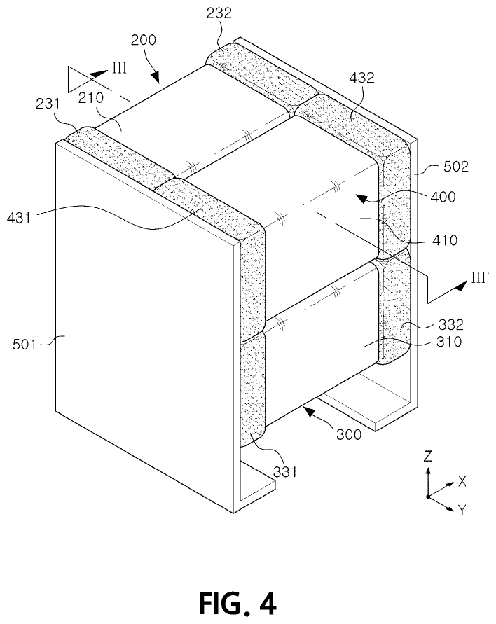

FIG. 4 is a schematic perspective view of a composite electronic component according to another example embodiment of the present disclosure.

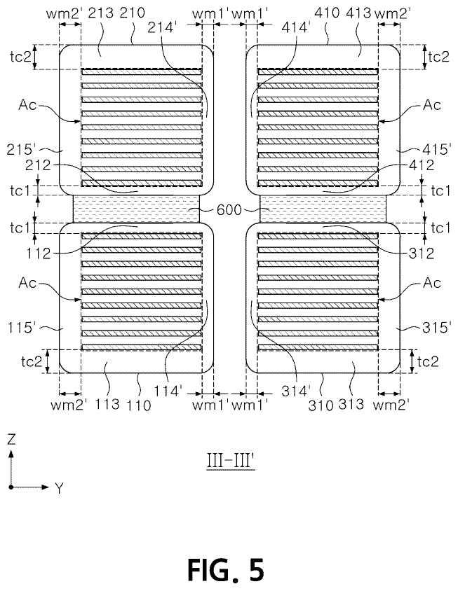

FIG. 5 is a schematic cross-sectional view taken along line III-III′ of FIG. 4.

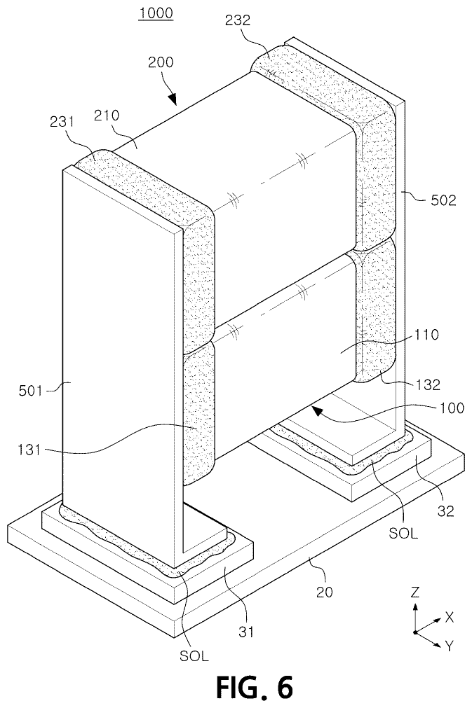

FIG. 6 is a schematic view of a board having the composite electronic component of FIG. 1 mounted thereon.

Hereinafter, a multilayer electronic component according to an example embodiment of the present disclosure will be described in detail with reference to FIGS. 1 to 6. A multilayer ceramic capacitor is described as an example of a multilayer electronic component. However, the present disclosure may be applied to various electronic products using a dielectric composition, such as inductors, piezoelectric elements, varistors, thermistors, or the like.

A composite electronic component 10 according to an example embodiment of the present disclosure may include a plurality of multilayer electronic components 100 and 200 including a body 110 including a capacitance formation portion Ac including a dielectric layer 111 and internal electrodes 121 and 122 alternately disposed with the dielectric layer 111 in a first direction, and cover portions 112 and 113 disposed on both side surfaces of the capacitance formation portion Ac in the first direction, and external electrodes 131 and 132 disposed on the body 110 in a second direction, perpendicular to the first direction. The plurality of multilayer electronic components 100 and 200 may include a pair of multilayer electronic components 100 and 200 disposed to be in contact with each other in the first direction. When, among cover portions 112, 113, 212, and 213 of the pair or the plurality of multilayer electronic components, cover portions disposed to be adjacent to each other in the first direction are referred to as first cover portions 112 and 212 and cover portions disposed to not be adjacent to each other in the first direction are referred to as second cover portions 113 and 213, an average dimension of the dielectric layer 111 in the first direction is referred to as td, an average dimension of each of the first cover portions 112 and 212 in the first direction is referred to as tc1, and an average dimension of each of the second cover portions 113 and 213 in the first direction is referred to as tc2, 0.5×td≤tc1<tc2 may be satisfied.

Hereinafter, a multilayer electronic component 100 will be described in more detail, but unless otherwise inconsistent therewith, descriptions of the multilayer electronic component 100 may be equally applied to other multilayer electronic components 200, 300, and 400.

In the body 110, the dielectric layer 111 and the internal electrodes 121 and 122 may be alternately stacked.

More specifically, the body 110 may include the capacitance formation portion Ac disposed in the body 110, the capacitance formation portion Ac including a first internal electrode 121 and a second internal electrode 122 alternately disposed to each other with the dielectric layer 111 interposed therebetween to form capacitance.

A specific shape of the body 110 is not limited. However, as illustrated, the body 110 may have a hexahedral shape or a shape similar thereto. During a sintering process, ceramic particles included in the body 110 may shrink, such that the body 110 may not have a hexahedral shape having perfectly straight lines, but may have a substantially hexahedral shape.

The body 110 may have first and second surfaces 1 and 2 opposing each other in the first direction, third and fourth surfaces 3 and 4 connected to the first and second surfaces 1 and 2, the third and fourth surfaces 3 and 4 opposing each other in the second direction, and fifth and sixth surfaces 5 and 6 connected to the first to fourth surfaces 1, 2, 3, and 4, the fifth and sixth surfaces 5 and 6 opposing each other in the third direction.

A plurality of dielectric layers 111, included in the body 110, may be in a sintered state, and adjacent dielectric layers 111 may be integrated with each other such that boundaries therebetween are not readily apparent without using a scanning electron microscope (SEM).

A raw material included in the dielectric layer 111 is not limited as long as sufficient capacitance is obtainable therewith. In general, a perovskite (ABO₃)-based material may be used. For example, a barium titanate-based material, a lead composite perovskite-based material, or a strontium titanate-based material may be used. The barium titanate-based material may include BaTiO₃-based ceramic particles. Examples of the ceramic particles may include BaTiO₃, and (Ba₁₋ₓCaₓ)TiO₃ (0<x<1), Ba(Ti_{1-y}Ca_{y})O₃ (0<y<1), (Ba₁₋ₓCaₓ) (Ti_{1-y}Zr_{y})O₃ (0<x<1, 0<y<1), or Ba(Ti_{1-y}Zr_{y})O₃ (0<y<1) obtained by partially dissolving Ca or Zr in BaTiO₃.

In addition, a raw material, included in the dielectric layer 111, may be obtained by adding various ceramic additives, organic solvents, binders, dispersants, and the like to particles such as barium titanate (BaTiO₃) depending on the purpose of the present disclosure.

In order to distinguish from a dielectric layer to be described below included in the cover portions 112 and 113 and a side margin region, a dielectric layer included in the capacitance formation portion Ac may be defined as a first dielectric layer, a dielectric layer included in the cover portions 112 and 113 may be defined as a second dielectric layer, and a dielectric layer formed by a method of forming the side margin region may be defined as a third dielectric layer. The first to third dielectric layers may be the same or at least partially different from each other. However, unless otherwise specified, descriptions of the dielectric layer in the present disclosure may correspond to descriptions of the first dielectric layer.

In addition, the first and second dielectric layers may be formed using a dielectric material such as barium titanate (BaTiO₃), and thus may include a dielectric microstructure after sintering. The dielectric microstructure may include a plurality of grains, a grain boundary disposed between adjacent grains, and a triple point disposed at a point with which three or more grain boundaries are in contact, and may include a plurality of grains, a plurality of grain boundaries, and a plurality of triple points.

A dimension (td) of the dielectric layer 111 in the first direction is not limited.

However, in order to improve withstand voltage properties of the multilayer electronic component 100, the dimension (td) of the dielectric layer 111 in the first direction may be 10.0 μm or less, 9.0 μm or less, 8.0 μm or less, 6.0 μm or less, 5.0 μm or less, 4.0 μm or less, 3.0 μm or less, 2.0 μm or less, or 1.0 μm or less. In order to more easily achieve miniaturization and high capacitance, the dimension (td) of the dielectric layer 111 in the first direction may be 0.8 μm or less, 0.6 μm or less, or 0.4 μm or less.

Here, the dimension (td) of the dielectric layer 111 in the first direction may refer to a dimension (td) of the dielectric layer 111 in the first direction, disposed between the first and second internal electrodes 121 and 122.

The dimension (td) of the dielectric layer 111 in the first direction may refer to a dimension, distance, size, or length of the dielectric layer 111 in the first direction, or may refer to a thickness of the dielectric layer.

In this case, the dimension (td) of the dielectric layer 111 in the first direction may be based on a concept including a dimension (td) of at least one of the plurality of dielectric layers 111 in the first direction, or may be based on a concept including a dimension (td) of each of all the dielectric layers 111 in the first direction.

In addition, the dimension (td) of the dielectric layer 111 in the first direction may refer to an average dimension (td) of a single dielectric layer 111 in the first direction, may refer to an average dimension (td) of each of the plurality of dielectric layers 111 in the first direction, or may refer to average dimensions (td) of the plurality of dielectric layers 111 in the first direction.

The average dimension (td) of the dielectric layer 111 in the first direction, as described in the present disclosure, may be measured by scanning, with an SEM, an image of a cross-section of the body 110 in the first and second directions at a magnification of 10,000. More specifically, the average dimension (td) of the single dielectric layer 111 in the first direction may refer to an average value of dimensions of the single dielectric layer 111 in the first direction, measured at five points spaced apart from each other at equal intervals in the second direction, in the scanned image. Other methods and/or tools appreciated by one of ordinary skill in the art, even if not described in the present disclosure, may also be used.

In addition, when such average value measurement is performed on three dielectric layers 111, an average dimension (td) of the plurality of dielectric layers 111 in the first direction may be further generalized.

The internal electrodes 121 and 122 may be alternately stacked with the dielectric layer 111.

The internal electrodes 121 and 122 may include a first internal electrode 121 and a second internal electrode 122. The first and second internal electrodes 121 and 122 may be alternately disposed to oppose each other, with the dielectric layer 111, included in the body 110, interposed therebetween, and may be exposed to the third and fourth surfaces 3 and 4 of the body 110, respectively.

More specifically, the first internal electrode 121 may be spaced apart from the fourth surface 4 and be exposed through the third surface 3, and the second internal electrode 122 may be spaced apart from the third surface 3 and be exposed through the fourth surface 4. A first external electrode 131 may be disposed on the third surface 3 of the body 110 and be connected to the first internal electrode 121, and a second external electrode 132 may be disposed on the fourth surface 4 of the body 110 and be connected to the second internal electrode 122.

That is, the first internal electrode 121 may not be connected to the second external electrode 132, but may be connected to the first external electrode 131, and the second internal electrode 122 may not be connected to the first external electrode 131, but may be connected to the second external electrode 132. In this case, the first and second internal electrodes 121 and 122 may be electrically isolated from each other by the dielectric layer 111 interposed therebetween.

The body 110 may be formed by alternately stacking a first ceramic green sheet on which a first internal electrode paste, which will be the first internal electrode 121, is printed and a second ceramic green sheet on which a second internal electrode paste, which will be the second internal electrode 122, is printed and then performing sintering thereon.

A material included in the internal electrodes 121 and 122 is not limited, and a material having excellent electrical conductivity may be used. For example, the internal electrodes 121 and 122 may include at least one of nickel (Ni), copper (Cu), palladium (Pd), silver (Ag), gold (Au), platinum (Pt), tin (Sn), tungsten (W), titanium (Ti), and alloys thereof.

In addition, the internal electrodes 121 and 122 may be formed by printing, on a ceramic green sheet, a conductive paste for internal electrodes including at least one of nickel (Ni), copper (Cu), palladium (Pd), silver (Ag), gold (Au), platinum (Pt), tin (Sn), tungsten (W), titanium (Ti), and alloys thereof. A screen-printing method or a gravure-printing method may be used as a method of printing the conductive paste for internal electrodes, but the present disclosure is not limited thereto.

A dimension (te) of each of the internal electrodes 121 and 122 in the first direction is not limited. Hereinafter, the dimension (te) of each of the internal electrodes 121 and 122 in the first direction may refer to a dimension (te) of each of the first internal electrode 121 and the second internal electrode 122 in the first direction.

In order to achieve miniaturization and high capacitance of the multilayer electronic component 100, the dimension (te) of each of the internal electrodes 121 and 122 in the first direction may be 3.0 μm or less, 2.0 μm or less, or 1.0 μm or less. In order to more easily achieve ultra miniaturization and high capacitance, the dimension (te) of each of the internal electrodes 121 and 122 in the first direction may be 0.8 μm or less or 0.6 μm or less, and more preferably 0.4 μm or less.

The dimension (te) of each of the internal electrodes 121 and 122 in the first direction may be based on a concept including a dimension (te) of at least one of a plurality of internal electrodes 121 and 122 in the first direction, or may be based on a concept including dimensions (te) of all the internal electrodes 121 and 122 in the first direction.

Here, the dimension (te) of each of the internal electrodes 121 and 122 in the first direction may refer to a dimension, distance, size, or length of each of the internal electrodes 121 and 122 in the first direction, or may refer to a thickness of each of the internal electrodes 121 and 122.

In this case, the dimension (te) of each of the internal electrodes 121 and 122 in the first direction may be based on a concept including a dimension (te) of at least one of the plurality of internal electrodes 121 and 122 in the first direction, or may be based on a concept including a dimension (te) of each of all the internal electrodes 121 and 122 in the first direction.

In addition, the dimension (te) of each of the internal electrodes 121 and 122 in the first direction may refer to an average dimension (te) of each of the internal electrodes 121 and 122 in the first direction, may refer to an average dimension (te) of each of the plurality of internal electrodes 121 and 122 in the first direction, or may refer to average dimensions (te) of the plurality of internal electrodes 121 and 122 in the first direction.

The average dimension (te) of each of the internal electrodes 121 and 122 in the first direction may be measured by scanning, with an SEM, an image of a cross-section of the body 110 in the first and second directions at a magnification of 10,000. More specifically, the average dimension (te) of each of the internal electrodes 121 and 122 in the first direction may be an average value of dimensions of each of the internal electrodes 121 and 122, measured at five points spaced apart from each other at equal intervals in the second direction, in the scanned image. The five points, spaced apart from each other at equal intervals, may be designated in the capacitance formation portion Ac. In addition, when such average value measurement is performed on three internal electrodes 121 and 122, the average dimensions (te) of the plurality of internal electrodes 121 and 122 in the first direction may be further generalized.

The body 110 may include cover portions 112 and 113, disposed on both end surfaces (or both surfaces) of the capacitance formation portion Ac in the first direction.

The cover portions 112 and 113 may be formed by disposing, respectively, a single second dielectric layer or two or more second dielectric layers on both surfaces of the capacitance formation portion Ac in the first direction, or by stacking the second dielectric layers in the first direction, and may basically serve to prevent damage to the internal electrodes 121 and 122 caused by physical or chemical stress.

The cover portions 112 and 113 may not include the internal electrodes 121 and 122, and may include a dielectric material. That is, the cover portions may include a dielectric material, and, for example, may include a barium titanate (BaTiO₃)-based dielectric material.

In addition, the cover portions 112 and 113 may include at least one of magnesium (Mg), tin (Sn), zirconium (Zr), aluminum (Al), calcium (Ca), silicon (Si), and gallium (Ga) in order to improve mechanical or electrical properties.

A dimension of each of the cover portions 112 and 113 in the first direction is not limited.

However, in order to improve reliability of the multilayer electronic component 100 under a high-voltage environment, dimensions (tc1 and tc2) of the cover portions 112 and 113 in the first direction may be 300 μm or less, 250 μm or less, 200 μm or less, 150 μm or less, or 100 μm or less. To more easily achieve miniaturization and high capacitance, the dimensions (tc1 and tc2) of the cover portions 112 and 113 in the first direction may be 100 μm or less or 50 μm or less, preferably 30 μm or less, and more preferably 20 μm or less in ultra-compact products.

Here, the dimensions (tc1 and tc2) of the cover portions 112 and 113 in the first direction may be based on a concept including a dimension, distance, size, or length of each of the cover portions 112 and 113 in the first direction, or may be based on a concept including a thickness of each of the cover portions 112 and 113.

In addition, the dimensions (tc1 and tc2) of the cover portions 112 and 113 in the first direction may be based on a concept including average dimensions (tc1 and tc2) of the cover portions 112 and 113 in the first direction, disposed on both surfaces of the capacitance formation portion Ac in the first direction.

The average dimensions (tc1 and tc2) of the cover portions 112 and 113 in the first direction may be measured by scanning, with an SEM, an image of a cross-section of the body 110 in the first and second directions at a magnification of 10,000. More specifically, each of the average dimensions (tc1 and tc2) of the cover portions 112 and 113 in the first direction may refer to an average value of dimensions of one of the cover portions, measured at five points spaced apart from each other at equal intervals in the second direction, in the scanned image. An average dimension of the other cover portion in the first direction may be obtained in the same manner. Other methods and/or tools appreciated by one of ordinary skill in the art, even if not described in the present disclosure, may also be used.

Regions of the multilayer electronic component 100 between the capacitance formation portion Ac and both surfaces of the body 110 in the third direction may be referred to as side margin regions 114 and 115.

More specifically, the side margin regions 114 and 115 may refer to a region 114 between the internal electrodes 121 and 122 and the fifth surface 5, and a region 115 between the internal electrodes 121 and 122 and the sixth surface 6. Unless otherwise inconsistent therewith, descriptions of the side margin regions 114 and 115 may be descriptions of each of the region 114 between the internal electrodes 121 and 122 and the fifth surface 5, and the region 115 between the internal electrodes 121 and 122 and the sixth surface 6.

As illustrated, the side margin regions 114 and 115 may refer to regions between both ends of the first and second internal electrodes 121 and 122 in a third direction and a surface of the body 110, based on a cross-section of the body 110 in the first and third directions.

The side margin regions 114 and 115 may refer to regions of a ceramic green sheet for the capacitance formation portion Ac, other than the internal electrodes 121 and 122, when a conductive paste for internal electrodes is applied to the ceramic green sheet excluding regions in which the side margin regions 114 and 115 are to be formed.

Alternatively, the side margin regions 114 and 115 may be formed by applying a conductive paste to a ceramic green sheet for the capacitor formation portion Ac, excluding regions in which the side margin regions 114 and 115 are to be formed, to form the internal electrodes 121 and 122, and then, in order to suppress a step portion caused by the internal electrodes 121 and 122, cutting the stacked internal electrodes 121 and 122 to expose the internal electrodes 121 and 122 in the third direction, and disposing or stacking, in the third direction, a single third dielectric layer or two or more third dielectric layers on both end surfaces of the capacitor formation portion Ac in the third direction.

The side margin regions 114 and 115 may basically serve to prevent damage to the internal electrodes 121 and 122 due to physical or chemical stress.

The side margin regions 114 and 115 may not include the internal electrodes 121 and 122, and may be formed of a material the same as that of the first dielectric layer 111. For example, the side margin regions 114 and 115 may be portions of the first dielectric layer 111. That is, the side margin regions 114 and 115 may include a dielectric material, and, for example, may include a barium titanate (BaTiO₃)-based dielectric material.

A dimension (wm′) of each of the side margin regions 114 and 115 in the third direction is not limited.

Hereinafter, the dimension (wm′) of each of the side margin regions 114 and 115 in the third direction may refer to a dimension (wm′) of each of the region 114 between the internal electrodes 121 and 122 and the fifth surface 5, and the region 115 between the internal electrodes 121 and 122 and the sixth surface 6.

In order to more easily achieve miniaturization and high capacitance of the multilayer electronic component 100, the dimension (wm′) of each of the side margin regions 114 and 115 in the third direction may be 50 μm or less, preferably 30 μm or less, and more preferably 20 μm or less for ultra-small products.

Here, the dimension (wm′) of each of the side margin regions 114 and 115 in the third direction may refer to a dimension, distances, size, or length of each of the side margin regions 114 and 115 in the third direction, or may refer to a width of each of the side margin regions 114 and 115.

In addition, the dimension (wm′) of each of the side margin regions 114 and 115 in the third direction may refer to an average dimension (wm′) of each of the respective side margin regions 114 and 115 in the third direction.

The average dimension (wm′) of each of the side margin portions 114 and 115 in the third direction may be measured by scanning, with an SEM, an image of a cross-section of the body 110 in the first and third directions at a magnification of 10,000. More specifically, the average dimension (wm′) of each of the side margin portions 114 and 115 in the third direction may refer to an average value of dimensions of one of the side margin portions, measured at five points spaced apart from each other at equal intervals in the first direction, in the scanned image. An average dimension of the other side margin portion in the third direction may be obtained in the same manner. Other methods and/or tools appreciated by one of ordinary skill in the art, even if not described in the present disclosure, may also be used.

In an example embodiment of the present disclosure, a structure in which the multilayer electronic component 100 has two external electrodes 131 and 132, the number, shape, or the like of the external electrodes 131 and 132 may vary depending on a form of the internal electrodes 121 and 122 or other purposes.

The external electrodes 131 and 132 may be disposed on the body 110, and may be connected to the internal electrodes 121 and 122.

More specifically, the external electrodes 131 and 132 may include first and second external electrodes 131 and 132 respectively disposed on third and fourth surfaces 3 and 4 of the body 110, the first and second external electrodes 131 and 132 respectively connected to the first and second internal electrodes 121 and 122. That is, the first external electrode 131 may be disposed on the third surface 3 of the body, and may be connected to the first internal electrode 121, and the second external electrode 132 may be disposed on the fourth surface 4 of the body, and may be connected to the second internal electrode 122.

In addition, the external electrodes 131 and 132 may be disposed on a portion of the first and second surfaces 1 and 2 of the body 110 to extend, or may be disposed on a portion of the fifth and sixth surfaces 5 and 6 of the body 110 to extend. That is, the first external electrode 131 may be disposed on the third surface 3 of the body 110 and a portion of the first, second, fifth, and sixth surfaces 1, 2, 5, and 6 of the body 110, and the second external electrode 132 may be disposed on the fourth surface 4 of the body 110 and a portion of the first, second, fifth, and sixth surfaces 1, 2, 5, and 6 of the body 110 of the body 110.

The external electrodes 131 and 132 may be formed of any material having electrical conductivity, such as a metal or the like, and a specific material may be determined in consideration of electrical properties, structural stability, or the like. In addition, the external electrodes 131 and 132 may have a multilayer structure.

For example, the external electrodes 131 and 132 may include first electrode layers 131a and 132a disposed on the body 110, and second electrode layers 131b and 132b disposed on the first electrode layers 131a and 132a.

Here, the first and second electrode layers 131a, 132a, 131b, and 132b may preferably correspond to mutually distinct layers. However, the present disclosure is not limited thereto. The classification into the first and second electrode layers 131a, 132a, 131b, and 132b may merely reflect the order of manufacturing processes. The first and second electrode layers 131a, 132a, 131b, and 132b may not be distinguishable from each other and may be observed as a single layer.

In the present disclosure, the term “distinct” may refer to two layers being distinguishable due to a physical difference, a chemical difference, and/or a simple optical difference. The present disclosure is not limited thereto. However, the distinction between layers may be determined based on the presence or absence of an “interface.” The interface may refer to a surface on which two layers in contact with each other are distinguishable, and, for example, may refer to a surface on which the two layers are distinguishable due to a component difference observed through EDS analysis using equipment such as an SEM.

The first electrode layers 131a and 132a may be formed by transferring a sheet including a conductive metal onto the body 110, or by applying a conductive paste for external electrodes including a conductive metal to the body 110 and then sintering the conductive paste. Alternatively, the first electrode layers 131a and 132a may be formed by a dipping method in which the body 110 is immersed in the conductive paste for external electrodes including a conductive metal. However, the present disclosure is not limited thereto.

As a more specific example of the first electrode layers 131a and 132a, the first electrode layers 131a and 132a may be sintered electrodes including a conductive metal and glass.

As the conductive metal included in the first electrode layers 131a and 132a, a material having excellent electrical conductivity may be used. For example, the conductive metal may include at least one selected from the group consisting of nickel (Ni), copper (Cu), palladium (Pd), silver (Ag), gold (Au), platinum (Pt), tin (Sn), tungsten (W), titanium (Ti), and alloys thereof, but the present disclosure is not limited thereto.

The glass included in the first electrode layers 131a and 132a may serve to improve adhesion to the body 110.

The second electrode layers 131b and 132b may serve to improve mounting properties, and may be plating layers formed on the first electrode layers 131a and 132a using a plating method, but the present disclosure is not limited thereto.

The types of the second electrode layers 131b and 132b are not limited, and, for example, may include at least one selected from nickel (Ni), tin (Sn), silver (Ag), palladium (Pd), and alloys thereof.

The second electrode layers 131b and 132b may be a single layer or a plurality of layers.

More specifically, for example, the second electrode layers 131b and 132b may be a nickel (Ni) electrode layer or a tin (Sn) electrode layer, and may have a structure in which a nickel (Ni) electrode layer and a tin (Sn) electrode layer are sequentially formed on the first electrode layers 131a and 132a, or a structure in which a tin (Sn) electrode layer, a nickel (Ni) electrode layer, and a tin (Sn) electrode layer are sequentially formed. In addition, the second electrode layers 131b and 132b may include a plurality of nickel (Ni) electrode layers and/or a plurality of tin (Sn) electrode layers.

A size of each of the multilayer electronic components 100, 200, 300, and 400 is not limited.

However, to improve reliability under a high-voltage environment, the multilayer electronic components 100, 200, 300, and 400 having a size of 3216 (length×width: 3.2 mm×1.6 mm, with a tolerance of ±10% for length and width) or more, such as a size of 3216, 3225, 4520, 4532, 5750, or 5763, may exhibit more significant effects according to the present disclosure.

In addition, to simultaneously achieve miniaturization and high capacitance, a dielectric layer and an internal electrode may need to have a reduced thickness to increase the number of stacked layers. Thus, the multilayer electronic components 100, 200, 300, and 400 having a size of 2012 (length×width: 2.0 mm×1.2 mm, with a tolerance of ±10% for length and width) or less, such as a size of 2012, 1005, 0603, or 0402, may exhibit more significant effects according to the present disclosure.

Hereinafter, the composite electronic component 10 according to an example embodiment of the present disclosure will be described in more detail.

First, in an example embodiment of the present disclosure, the composite electronic component 10 may include a plurality of multilayer electronic components 100 and 200, and the plurality of multilayer electronic components 100 and 200 may be disposed to be in contact with each other in a first direction. That is, a pair of multilayer electronic components 100 and 200 may be disposed to be in contact with each other in the first direction.

In the drawings, the pair of multilayer electronic components 100 and 200, disposed to be in contact with each other in the first direction, are illustrated, but the present disclosure is not limited thereto. For example, three or more multilayer electronic components, that is, a plurality of multilayer electronic components, may be disposed to be in contact with each other in the first direction.

For ease of description, the multilayer electronic components may be defined as a first multilayer electronic component 100 and a second multilayer electronic component 200, respectively.

When, among cover portions 112, 113, 212, and 213 of the plurality of multilayer electronic components 100 and 200, cover portions disposed to be adjacent to each other in the first direction are referred to as first cover portions 112 and 212 and cover portions disposed to not be adjacent to each other in the first direction are referred to as second cover portions 113 and 213, an average dimension of the dielectric layer 111 in the first direction is referred to as td, an average dimension of each of the first cover portions 112 and 212 in the first direction is referred to as tc1, and an average dimension of each of the second cover portions 213 and 313 in the first direction is referred to as tc2, 0.5×td≤tc1<tc2 may be satisfied.

The plurality of multilayer electronic components 100 and 200 included in the composite electronic component 10 may satisfy 0.5×td≤tc1<tc2, such that the composite electronic component 10 may have improved dielectric capacitance, and may have more excellent withstand voltage properties. Such effects may result from reducing unnecessary thicknesses of the cover portions and accordingly adjusting thicknesses of the dielectric layer and internal electrodes, or may result from increasing the number of stacked layers. However, the present disclosure is not limited thereto.

More specifically, with reference to FIG. 2, an average dimension of one of the plurality of dielectric layers 111 of the first multilayer electronic component 100 in the first direction, or an average dimension of one of the plurality of dielectric layers 211 of the second multilayer electronic component 200 in the first direction may be referred to as td.

In addition, among the cover portions 112 and 113 of the first multilayer electronic component 100, a cover portion disposed to be adjacent to the second multilayer electronic component 200 in the first direction may be referred to as the first cover portion 112, and a cover portion disposed to not be adjacent to the second multilayer electronic component 200 in the first direction may be referred to as the second cover portion 113. In addition, among the cover portions 212 and 213 of the second multilayer electronic component 200, a cover portion disposed to be adjacent to the first multilayer electronic component 100 in the first direction may be referred to as the first cover portion 212, and a cover portion disposed to not be adjacent to the first multilayer electronic component 100 in the first direction may be referred to as the second cover portion 213. The average dimension of each of the first cover portions 112 and 212 in the first direction may be referred to as tc1, and the average dimension in the first direction of each of the second cover portions 113 and 213 may be referred to as tc2.

In the present disclosure, the first cover portions 112 and 212 may refer to the first cover portion 112 of the first multilayer electronic component 100 and the first cover portion 212 of the second multilayer electronic component 200, respectively. Similarly, the second cover portions 113 and 213 may refer to the second cover portion 113 of the first multilayer electronic component 100 and the second cover portion 213 of the second multilayer electronic component 200, respectively.

When three multilayer electronic components are disposed to be in contact with each other in the first direction, both of two cover portions disposed on the capacitance formation portion, in the first direction, of an intermediate multilayer electronic component may be first cover portions having an average dimension in the first direction that is tc1.

The plurality of multilayer electronic components 100 and 200 disposed to be in contact with each other in the first direction may mean that the same external electrodes are disposed to be in contact with each other, or that a conductive adhesive is disposed between external electrodes, and thus the plurality of multilayer electronic components 100 and 200 are disposed to be in contact with each other, including the conductive adhesive.

For example, the first external electrode 131 of the first multilayer electronic component and the first external electrode 231 of the second multilayer electronic component may be disposed to be in contact with each other. Similarly, the second external electrode 132 of the first multilayer electronic component and the second external electrode 232 of the second multilayer electronic component may be disposed to be in contact with each other.

When a conductive adhesive is applied, it may mean that the conductive adhesive is disposed between the first external electrode 131 of the first multilayer electronic component and the first external electrode 231 of the second multilayer electronic component, and applied so as to connect the first external electrode 131 of the first multilayer electronic component and the first external electrode 231 of the second multilayer electronic component to each other. Similarly, it may mean that the conductive adhesive is disposed between the second external electrode 132 of the first multilayer electronic component and the second external electrode 232 of the second multilayer electronic component, and applied so as to connect the second external electrode 132 of the first multilayer electronic component and the second external electrode 232 of the second multilayer electronic component to each other.

The conductive adhesive may be formed of any material having electrical conductivity, such as a metal or the like, and a specific material may be determined in consideration of electrical properties, structural stability, or the like.

In order to distinguish from a conductive adhesive to be described below disposed between an external electrode and a metal frame, a conductive adhesive disposed between external electrodes may be defined as a first conductive adhesive, and a conductive adhesive disposed between an external electrode and a metal frame may be defined as a second conductive adhesive.

When the plurality of multilayer electronic components 100 and 200 are disposed to be in contact only with each other in the first direction, average dimensions (wm′) of side margin regions 114, 115, 214, and 215 of the multilayer electronic components 100 and 200 in the third direction may be substantially the same. Here, “the average dimensions (wm′) of the side margin regions 114, 115, 214, and 215 in the third direction is substantially the same” may mean that the average dimensions (wm′) of the side margin regions 114, 115, 214, and 215 fall within a tolerance range of ±10% based on an average value of a maximum value and a minimum value, among the average dimensions of the side margin regions 114, 115, 214, and 215 in the third directions.

In an example embodiment of the present disclosure, the first cover portion 112 and the second cover portion 113 may have different compositions.

In the present disclosure, “having different compositions” may be based on a concept including a case in which different elements are included, as well as a case in which the same elements are included but in different content ratios.

As described above, in order to improve mechanical or electrical properties, the cover portions 112 and 113 may include at least one of magnesium (Mg), tin (Sn), zirconium (Zr), aluminum (Al), calcium (Ca), silicon (Si), and gallium (Ga), and the first cover portion 112 and the second cover portion 113 may include different sub-component elements.

Here, “the same elements being included but in different content ratios” may mean that a content of a second element differs from that of a first element by at least 3 atomic percent (at %) relative to 100 at % of the first element. The first element and the second element may both be included in the first cover portion 112 and the second cover portion 113. For example, when the first cover portion 112 and the second cover portion 113 include titanium (Ti) and magnesium (Mg), an atomic percentage of magnesium (Mg) relative to100 at % of titanium (Ti) in the first cover portion 112 may be referred to as a at %, and an atomic percentage of magnesium (Mg) in the second cover portion 113 may be referred to as R at %. When 3 at %≤|α-β| is satisfied, it may be considered that the first and second cover portions 112 and 113 have different compositions. Here, the atomic percentage may refer to an average atomic percentage, and may be measured by energy dispersive spectroscopy (EDS) using equipment such as an SEM or a transmission electron microscope (TEM).

In an example embodiment of the present disclosure, the first cover portion 112 and the second cover portion 113 may have different porosities.

Here, “having different porosities” may mean that a difference in porosity between the first cover portion 112 and the second cover portion 113, measured using the same measuring equipment or method, is 5% or more, and may mean that the porosity of the first cover portion 112 is less than that of the second cover portion 113.

The porosity of the first cover portion 112, having a relatively smaller average dimension in the first direction, may be reduced, thereby improving a sintered density of the first cover portion 112 and mechanical properties of the first cover portion 112.

In another example embodiment of the present disclosure, the plurality of multilayer electronic components may be further disposed to be in contact with each other in the third direction. More specifically, referring to FIGS. 4 and 5, the first and second multilayer electronic components 100 and 200 may be disposed to be in contact with each other in the first direction, the third and fourth multilayer electronic components 300 and 400 may be disposed to be in contact with each other in the first direction, and the first and second multilayer electronic components 100 and 200 and the third and fourth multilayer electronic components 300 and 400 may be disposed to be in contact with each other in the third direction.

In the drawings, it is illustrated that one pair of multilayer electronic components 100 and 200 and another pair of multilayer electronic components 300 and 400 are disposed to be in contact with each other in the third direction, but the present disclosure is not limited thereto. Three or more multilayer electronic components, that is, a plurality of multilayer electronic components, may be disposed to be in contact with each other in the third direction.

When, among side margin regions 114′, 115′, 214′, 215′, 314′, 315′, 414′, and 415′ of the plurality of multilayer electronic components 100, 200, 300, and 400, side margin regions disposed to be adjacent to each other in the third direction are referred to as first side margin regions 114′, 214′, 314′, and 414′ and side margin regions disposed to not be adjacent to each other are referred to as second side margin regions 115′, 215′, 315′, and 415′, an average dimension of each of the first side margin regions 114′, 214′, 314′, and 414′ in the third direction is referred to as wm1′, and an average dimension of each of the second side margin regions 115′, 215′, 315′, and 415′ in the third direction is referred to as wm2′, wm1′<wm2′ may be satisfied. wm1′ and wm2′ are measured in the same manner as wm′. Other methods and/or tools appreciated by one of ordinary skill in the art, even if not described in the present disclosure, may also be used.

The plurality of multilayer electronic components 100, 200, 300, and 400 included in the composite electronic component 10 may satisfy wm1′<wm2′, thereby improving an effective area of an internal electrode to improve dielectric capacitance, and improving impact resistance.

In this case, wm2′-wm1′ may preferably be 10 μm or more, 20 μm or more, 30 μm or more, 40 μm or more, 50 μm or more, or 100 μm or more, 110 μm or more, 120 μm or more, or 125 μm or more, but the present disclosure is not limited thereto.

More specifically, among the side margin regions 114′ and 115′ of the first multilayer electronic component 100, a side margin region disposed to be adjacent to a third multilayer electronic component 300 in the third direction may be referred to as a first side margin region 114′, and a side margin region disposed to not be adjacent to the third multilayer electronic component 300 in the third direction may be referred to as a second side margin region 115′. Among the side margin regions 214′ and 215′ of the second multilayer electronic component 200, a side margin region disposed to be adjacent to a fourth multilayer electronic 25 component 400 in the third direction may be referred to as a first side margin region 214′, and a side margin region disposed to not be adjacent to the fourth multilayer electronic component 400 in the third direction may be referred to as a second side margin region 215′. Among the side margin regions 314′ and 315′ of the third multilayer electronic component 300, a side margin region disposed to be adjacent to the first multilayer electronic component 100 in the third direction may be referred to as a first side margin region 314′, and a side margin region disposed to not be adjacent to the first multilayer electronic component 100 in the third direction may be referred to as a second side margin region 315′. Among the side margin regions 414′ and 415′ of the fourth multilayer electronic component 400, a side margin region disposed to be adjacent to the second multilayer electronic component 200 in the third direction may be referred to as a first side margin region 414′, and a side margin region disposed to not be adjacent to the second multilayer electronic component 200 in the third direction may be referred to as a second side margin region 415′.

In addition, an average dimension in the third direction of each of the first side margin region 114′ of the first multilayer electronic component 100, the first side margin region 214′ of the second multilayer electronic component 200, the first side margin region 314′ of the third multilayer electronic component 300, and the first side margin region 414′ of the fourth multilayer electronic component 400 may be referred to as wm1′. An average dimension in the third direction of each of the second side margin region 115′ of the first multilayer electronic component 100, the second side margin region 215′ of the second multilayer electronic component 200, the second side margin region 315′ of the third multilayer electronic component 300, and the second side margin region 415′ of the fourth multilayer electronic component 400 may be referred to as wm2′.

In the present disclosure, the first side margin regions 114′, 214′, 314′, and 414′ may respectively refer to the first side margin region 114′ of the first multilayer electronic component 100, the first side margin region 214′ of the second multilayer electronic component 200, the first side margin region 314′ of the third multilayer electronic component 300, and the first side margin region 414′ of the fourth multilayer electronic component 400. Similarly, the second side margin regions 115′, 215′, 315′, and 415′ may respectively refer to the second side margin region 115′ of the first multilayer electronic component 100, the second side margin region 215′ of the second multilayer electronic component 200, the second side margin region 315′ of the third multilayer electronic component 300, and the second side margin region 415′ of the fourth multilayer electronic component 400.

When three multilayer electronic components are disposed to be in contact with each other in the third direction, two side margin regions of an intermediate multilayer electronic component may both be first side margin regions having an average dimension in the third direction that is wm1′.

The composite electronic component 10 according to an example embodiment of the present disclosure may further include an insulating portion 600 disposed between bodies 110 and 210 of the plurality of multilayer electronic components 100 and 200.

More specifically, the insulating portion 600 may be disposed between the body 110 of the first multilayer electronic component and the body 210 of the second multilayer electronic component in the first direction, and may preferably be disposed to be in contact with the body 110 of the first multilayer electronic component and the body 210 of the second multilayer electronic component in the first direction.

As thicknesses of the first cover portions 112, 212 of the first and second multilayer electronic components decrease, the insulating portion 600 may serve to prevent a short circuit from occurring between the two components. The insulating portion 600 may be formed of any material having insulation properties, such as epoxy resin. In order to impart heat dissipation properties, a material having high thermal conductivity, such as alumina (Al₂O₃), may also be used.

The composite electronic component 10 according to an example embodiment of the present disclosure may include metal frames 501 and 502. The metal frames 501 and 502 may include a first metal frame 501 disposed on the first external electrode 131 in the second direction, and a second metal frame 502 disposed on the second external electrode 132 in the second direction.

The metal frames 501 and 502 may respectively include a connection portion disposed on the external electrodes 131 and 132 in the second direction, and a support portion connected to the connection portion, the support portion spaced apart from the first surface 1.

Here, connection between the connection portion and the support portion is not limited to direction connection between the connection between the connection portion and the support portion, and may be based on a concept including a structure in which another element, for example, a connecting portion having various shapes, is positioned between the connection portion and the support portion, and the connection portion and the support portion are indirectly connected to each other through the connecting portion.

A structure has been mainly described in which the first and second metal frames 501 and 502 are disposed on the first and second external electrodes 131 and132 of the first multilayer electronic component 100 in the second direction. However, unless otherwise inconsistent therewith, the metal frames 501 and 502 may also be disposed on the first and second external electrodes 231 and 232 of the second multilayer electronic component 200 in the second direction. In addition, the metal frames 501 and 502 may also be disposed on the first and second external electrodes 331, 332, 431, and 432 of the third and fourth multilayer electronic components 300, 400 in the second direction.

Although not illustrated in the drawings, the composite electronic component 10 according to an example embodiment of the present disclosure may further include a conductive adhesive disposed between the external electrodes 131 and 132 and the metal frames 501 and 502 to connect the external electrodes 131 and 132 and the metal frames 501 and 502 to each other. More specifically, the conductive adhesive may be disposed between the external electrodes 131 and 132 and the connection portions of the metal frames 501 and 502 to connect the external electrodes 131 and 132 and the connection portions to each other.

More specifically, the conductive adhesive may be disposed between the first external electrode 131 and the first metal frame 501 to connect the first external electrode 131 and the first metal frame 501 to each other, and may be disposed between the second external electrode 132 and the second metal frame 502 to connect the second external electrode 132 and the second metal frame 502 to each other.

A structure has been mainly described in which the conductive adhesive is between the first and second external electrodes 131 and 132 of the first multilayer electronic component 100 and the first and second metal frames 501 and 502. However, unless otherwise inconsistent therewith, the conductive adhesive may also be disposed between the first and second external electrodes 231, 232, 331, 332, 431, and 432 of the second to fourth multilayer electronic components 200, 300, and 400 and the metal frames 501 and 502.

The conductive adhesive may be formed of any material having electrical conductivity, such as a metal or the like, and a specific material may be determined in consideration of electrical properties, structural stability, or the like.

More specifically, for example, the conductive adhesive may include at least one selected from the group consisting of nickel (Ni), copper (Cu), palladium (Pd), silver (Ag), gold (Au), platinum (Pt), tin (Sn), tungsten (W), titanium (Ti), and alloys thereof, but the present disclosure is not limited thereto.

As described above, the conductive adhesive disposed between the external electrodes and the metal frames may be defined as a second conductive adhesive.

### Board Having Composite Electronic Component Mounted Thereon

According to another example embodiment of the present disclosure, a board having a composite electronic component mounted thereon 1000 may include a board 20, electrode pads 31 and 32 disposed on the board 20, and the composite electronic component 10 described above, and the composite electronic component 10 may be mounted on the board 20 so as to be bonded to the electrode pads 31 and 32.

In the present example embodiment, descriptions of the composite electronic component 10 may overlap the above descriptions of the composite electronic component 10, and thus the descriptions will be omitted.

The composite electronic component 10 may be connected to the electrode pads 31 and 32 by solder SOL disposed on lower surfaces of the metal frames 501 and 502. More specifically, first and second metal frames 501 and 502 may be connected to first and second electrode pads 31 and 32, respectively. In addition, the solder SOL may be applied so as not to rise to first and second connection portions of the metal frames 501 and 502, thereby reducing acoustic noise or vibrations, generated from the composite electronic component 10 and transferred to the board 20.

Hereinafter, the present disclosure will be described in further detail through experimental examples, which are provided to facilitate a specific understanding of the present disclosure and are not intended to limit the scope of the present disclosure.

### Experimental Examples

Experimental Example 1 may correspond to a 2-STACK MLCC in which two chips having a 5750 size (length×width: 5.7 mm×5.0 mm) are disposed to be in contact with each other in a first direction. The 2-STACK MLCC was manufactured such that a dielectric layer has a thickness of 5.2 μm, the number of stacked layers is 450, and one chip has a thickness of 2.513 mm. In this case, the 2-STACK MLCC was manufactured such that first cover portions disposed to be adjacent to each other respectively have a thickness of 250 μm, and second cover portions disposed to not be adjacent to each other respectively have a thickness of 250 μm.

Experimental Example 2 may correspond to a 2-STACK MLCC in which two chips having a 5750 size (length×width: 5.7 mm×5.0 mm) are disposed to be in contact with each other in a first direction. The 2-STACK MLCC was manufactured such that a dielectric layer has a thickness of 5.1 μm, the number of stacked layers is 467, and one chip has a thickness of 2.504 mm. In this case, the 2-STACK MLCC was manufactured such that first cover portions disposed to be adjacent to each other respectively have a thickness of 125 μm, and second cover portions disposed to not be adjacent to each other respectively have a thickness of 250 μm.

[Table 1] below sets forth the above-described basic specifications of Experimental Examples 1 and 2, and results of evaluation and/or measurement of withstand voltage and dielectric capacitance properties of each experimental example.

TABLE 1

| | |
|---|---|
| Experimental | Experimental |
| example 1 | example 2 |

| | | | | |
|---|---|---|---|---|
| Dielectric layer | 5.2 | μm | 5.1 | μm |

| | | |
|---|---|---|
| thickness (μm) | | |
| The number of stacked | 450 | 467 |

| | | | | |
|---|---|---|---|---|
| layers | | | | |
| Chip thickness (mm) | 2.513 | mm | 2.504 | mm |
| First cover portion | 250 | μm | 125 | μm |
| thickness (μm) | | | | |
| Second cover portion | 250 | μm | 250 | μm |
| thickness (μm) | | | | |
| Withstand voltage | 10.1 | V/μm | 10.1 | V/μm |

(V/μm)

| | | | | |
|---|---|---|---|---|
| dielectric | | | | |
| 2-STACK dielectric | 92.75 | μF | 96.26 | μF |

| | | |
|---|---|---|
| capacitance (μF) | | |
| Capacitance | 99% | 102% |
| Efficiency (%) | | |

Withstand voltages of Experimental Example 1 and Experimental Example 2 were 10.1 V/μm, and the same. However, a capacitance of Experimental Example was 92.75 μF, and a capacitance efficiency of Experimental Example was 99% relative to a target product. A capacitance of Experimental Example 2 was 96.26 μF, and a capacitance efficiency of Experimental Example 2 was 102% relative to the target product.

From the above results, it can be confirmed that, in a case where two MLCCs are disposed to be in contact with each other, capacitance properties are improved without degrading withstand voltage properties even when first cover portions disposed to be adjacent to each other have a small thickness.

Experimental Example 3 may correspond to a 2-STACK MLCC in which two chips having a 5750 size (length×width: 5.7 mm×5.0 mm) are disposed to be in contact with each other in a first direction. The 2-STACK MLCC may be manufactured such that a dielectric layer has a thickness of 7.6 μm, the number of stacked layers is 325, and one chip has a thickness of 2.506 mm. In this case, the 2-STACK MLCC may be manufactured such that first cover portions disposed to be adjacent to each other have a thickness of 250 μm, and second cover portions disposed to not be adjacent to each other have a thickness of 250 un.

Experimental Example 4 may correspond to a 2-STACK MLCC in which two chips having a 5750 size (length×width: 5.7 mm×5.0 mm) are disposed to be in contact with each other in a first direction. The 2-STACK MLCC may be manufactured such that a dielectric layer has a thickness of 7.8 μm, the number of stacked layers is 332, and one chip has a thickness of 2.512 mm. In this case, the 2-STACK MLCC may be manufactured such that first cover portions disposed to be adjacent to each other have a thickness of 125 μm, and second cover portions disposed to not be adjacent to each other have a thickness of 250 μm.

[Table 2] below sets forth the above-described basic specifications of Experimental Examples 3 and 4, and results of evaluation and/or measurement of withstand voltage and dielectric capacitance properties of each experimental example.

TABLE 2

| | |
|---|---|
| Experimental | Experimental |
| example 3 | example 4 |

| | | | | |
|---|---|---|---|---|
| Dielectric layer | 7.6 | μm | 7.8 | μm |

| | | |
|---|---|---|
| thickness (μm) | | |
| The number of stacked | 325 | 332 |

| | | | | |
|---|---|---|---|---|
| layers | | | | |
| Chip thickness (mm) | 2.506 | mm | 2.512 | mm |
| First cover portion | 250 | μm | 125 | μm |

thickness (μm)

| | | | | |
|---|---|---|---|---|
| Second cover portion | 250 | μm | 250 | μm |

| | | |
|---|---|---|
| thickness (μm) | | |
| Capacitance | 99% | 99% |

| | | | | |
|---|---|---|---|---|
| efficiency (%) | | | | |
| Withstand voltage | 9.9 | V/μm | 9.6 | V/μm |

(V/μm)

Capacitance efficiencies of Experimental Example 3 and Experimental Example 4 relative to a target product were 99%, and the same. However, a withstand voltage of Experimental Example 3 was evaluated to be 9.9 V/μm, whereas a withstand voltage of Experimental Example 4 was evaluated to be 9.6 V/μm.

From the above results, it can be confirmed that, in a case where two MLCCs are disposed to be in contact with each other, withstand voltage properties are improved without degrading capacitance properties even when first cover portions disposed to be adjacent to each other have a small thickness.

While example embodiments have been illustrated and described above, it will be apparent to those skilled in the art that modifications and variations could be made without departing from the scope of the present disclosure as defined by the appended claims.

In addition, the term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

The terms used herein are for the purpose of describing particular example embodiments only and are to not be limiting of the example embodiments. As used herein, the singular forms “a,” “an,” and “the” are intended to include the plural forms as well, unless the context clearly indicates otherwise.

What is claimed is:

1. A composite electronic component comprising:
a plurality of multilayer electronic components, each multilayer electronic component among the plurality of multilayer electronic components including:
a body including:
a capacitance formation portion including:
a dielectric layer, and
internal electrodes alternately disposed with the dielectric layer in a first direction, and
a cover portion that includes a first cover portion and a second cover portion, the first cover portion is disposed on a first side surface of the capacitance formation portion in the first direction, and the second cover portion is disposed on a second side surface of the capacitance formation portion in the first direction, and
an external electrode disposed on the body in a second direction that is perpendicular to the first direction,
wherein the plurality of multilayer electronic components include a pair of multilayer electronic components disposed to be in contact with each other in the first direction,
when, among the pair of multilayer electronic components, the first cover portions are disposed to be adjacent to each other in the first direction, and the second cover portions are disposed to not be adjacent to each other in the first direction, and
an average dimension of the dielectric layer in the first direction is referred to as td, an average dimension of the first cover portion in the first direction is referred to as tc1, and an average dimension of the second cover portion in the first direction is referred to as tc2, 0.5×td≤tc1<tc2 is satisfied.

2. The composite electronic component of claim 1, wherein the first cover portion and the second cover portion have different compositions.

3. The composite electronic component of claim 1, further comprising:
an insulating portion disposed between the bodies of the plurality of multilayer electronic components.

4. The composite electronic component of claim 1, further comprising:
a metal frame disposed on the external electrode in the second direction.

5. The composite electronic component of claim 4, further comprising:
a conductive adhesive disposed between the external electrode and the metal frame to connect the external electrode and the metal frame to each other.

6. The composite electronic component of claim 1,
wherein the body of the each multilayer electronic component further includes:
a first side margin region on a third side surface of the capacitance formation portion in a third direction, and
a second side margin region on a fourth side surface of the capacitance formation portion in the third direction, where the third direction is perpendicular to the first and second directions,
the plurality of multilayer electronic components include:
a third multilayer electronic component disposed to be in contact with at least one multilayer electronic component among the pair of multilayer electronic components in the third direction,
the first side margin region of the third multilayer electronic component and the first side margin region of the at least one multilayer electronic component among the pair of multilayer electronic components are disposed to be adjacent to each other in the third direction, and the second side margin region of the third multilayer electronic component and the second side margin region of the at least one multilayer electronic component among the pair of multilayer electronic components are disposed to not be adjacent to each other in the third direction, and
an average dimension of the first side margin region in the third direction is referred to as wm1′, and an average dimension of the second side margin region in the third direction is referred to as wm2′, wm1′<wm2′ is satisfied.

7. A composite electronic component comprising:
a plurality of multilayer electronic components, each multilayer electronic component among the plurality of multilayer electronic components including:
a body including:
a capacitance formation portion including:
a dielectric layer, and
internal electrodes alternately disposed with the dielectric layer in a first direction, and
a cover portion that includes a first cover portion and a second cover portion, the first cover portion is disposed on a first side surface of the capacitance formation portion in the first direction, and the second cover portion is disposed on a second side surface of the capacitance formation portion in the first direction, and
an external electrode disposed on the body in a second direction that is perpendicular to the first direction,
wherein the plurality of multilayer electronic components are disposed to be in contact with each other in the first direction,
when, among the plurality of multilayer electronic components, the first cover portions are disposed to be adjacent to each other in the first direction, and the second cover portions disposed to not be adjacent to each other in the first direction, and
an average dimension of the dielectric layer in the first direction is referred to as td, an average dimension of the first cover portion in the first direction is referred to as tc1, and an average dimension of the second cover portion in the first direction is referred to as tc2, 0.5×td≤tc1<tc2 is satisfied.

8. The composite electronic component of claim 7, wherein the first cover portion and the second cover portion have different compositions.

9. The composite electronic component of claim 7, further comprising:
an insulating portion disposed between the bodies of the plurality of multilayer electronic components.

10. The composite electronic component of claim 7, further comprising:
a metal frame disposed on the external electrode in the second direction.

11. The composite electronic component of claim 10, further comprising:
a conductive adhesive disposed between the external electrode and the metal frame to connect the external electrode and the metal frame to each other.

12. The composite electronic component of claim 1,
wherein the body of the each multilayer electronic component further includes a first side margin region on a third side surface of the capacitance formation portion in a third direction, and a second side margin region on a fourth side surface of the capacitance formation portion in the third direction, where the third direction is perpendicular to the first and second directions,
the plurality of multilayer electronic components include:
a multilayer electronic component disposed to be in contact with at least one other multilayer electronic component among the plurality of multilayer electronic components in the third direction,
the first side margin region of the multilayer electronic component and the first side margin region of the at least one other multilayer electronic component among the plurality of multilayer electronic components are disposed to be adjacent to each other in the third direction, and the second side margin region of the multilayer electronic component and the second side margin region of the at least one other multilayer electronic component among the plurality of multilayer electronic components are disposed to not be adjacent to each other in the third direction, and
an average dimension of the first side margin region in the third direction is referred to as wm1′, and an average dimension of the second side margin region in the third direction is referred to as wm2′, wm1′<wm2′ is satisfied.

13. A board having a composite electronic component mounted thereon, the board comprising:
a board;
an electrode pad disposed on the board; and
the composite electronic component of claim 1,
wherein the composite electronic component is mounted on the board so as to be bonded to the electrode pad.
